(19) United States
(12) Patent Application Publication
(10) Pub. No.: US 2026/0140175 A1
(43) Pub. Date: May 21, 2026

(54) SYSTEM AND METHOD FOR DEBUGGING CLB LOGIC ELEMENT STATES USING ONLY ONE PIN

(71) Applicant: Microchip Technology Incorporated, Chandler, AZ (US)

(72) Inventors: Attila Kolinger, Wels (AT); Josh Booth, Chandler, AZ (US)

(73) Assignee: Microchip Technology Incorporated, Chandler, AZ (US)

(21) Appl. No.: 19/252,281

(22) Filed: Jun. 27, 2025

Related U.S. Application Data
(60) Provisional application No. 63/723,488, filed on Nov. 21, 2024.

(51) Int. Cl. G01R 31/3177; G01R 31/317

(52) U.S. Cl. CPC G01R 31/3177; G01R 31/31705

(57) ABSTRACT

A system and method for debugging logic elements in a configurable logic block using only one pin. A synchronization pulse is generated, and each logic element is connected, in turn, using a digital selector switch. The synchronization pulse and a logic state of each logic element are received, in turn, by an output buffer. First, second, and third digital outputs levels are enabled on a single output line using a voltage divider configuration of resistors connected to the output line of the output buffer. The output levels include the synchronization pulse, a low logic state, and a high logic state. The synchronization pulse and the logic state of each logic element are outputted as the different output levels, in turn, via a single debug pin connected to an oscilloscope or other display device for visualization. The debug pin may be shared with other functions when not being used for debugging.

### RELATED APPLICATION

The present U.S. non-provisional patent application is related to and claims priority benefit of an earlier-filed U.S. provisional patent application titled “System for and Method of Debugging CLB Logic Element States Using One Pin,” Ser. No. 63/723,488, filed Nov. 21, 2024. The entire content of the identified earlier-filed application is incorporated by reference as if fully set forth herein.

### FIELD

The present disclosure relates to field-programmable gate arrays and methods of using them, and more particularly, the various examples described herein concern a system for debugging a plurality of logic elements in a configurable logic block or other small field-programmable gate array using only one pin, and a method for debugging a plurality of logic elements in a configurable logic block or other small field-programmable gate array using only one pin.

### BACKGROUND

A configurable logic block (CLB) is a small, reconfigurable field-programmable gate array (FPGA), or digital logic module, integrated into a microcontroller for performing hardware-based digital logic independent of a central processing unit. CLBs may be used to provide fast and reliable response times for a range of applications, including automotive and industrial applications. It is generally desirable to improve the performance and reduce the cost of CLBs, but it can be difficult to do so.

This background discussion is intended to provide related information, and is not necessarily prior art.

### SUMMARY

A system and method for debugging a plurality of logic elements (LEs) in a CLB or other small FPGA using only one pin. Broadly, a synchronization pulse and a logic state of each LE are outputted, in turn, as one of three different output levels (SYNC, low, and high) via a single debug pin connected to a display device (e.g., an oscilloscope) for visualization. Examples advantageously use no LEs and so are suitable for use with extremely low LE-count CLBs, allow for the visualization of LE logic states using a single debug pin while providing an easy debugging readout with a conventional oscilloscope and without reprogramming (i.e., without requiring a programming cycle), and are compatible with known static debugging techniques. Further, the debug pin may be shared with other functions when not being used for debugging.

In an example, a system is provided for debugging a plurality of LEs in an FPGA, wherein each LE is associated with a particular logic state. The system may include a synchronization pulse generator, a digital selector switch, an output buffer, a voltage divider resistor network, and a single debug pin. The synchronization pulse generator may be configured to generate a synchronization pulse. The digital selector switch may connect to each LE and output, in turn, the particular logic state of each LE. The output buffer may be configured to receive and output, in turn, the synchronization pulse and the particular logic state of each LE. The voltage divider resistor network may include first and second resistors and may be connected to an output line of the output buffer. The voltage divider resistor network may be configured to enable first, second, and third digital outputs levels on the output line. The digital output levels may correspond to the synchronization pulse, a low particular logic state, and a high particular logic state. The single debug pin may be connected to the output line of the output buffer after the voltage divider resistor network. The single debug pin may be configured to be connected to a display device for visualizing, in turn, the synchronization pulse and the particular logic state of each LE as the first, second, and third digital outputs levels.

The preceding example may further include any one or more of the following features. The FPGA may be a CLB, and the plurality of LEs may include between twenty-eight (28) and one hundred thirty-two (132) LEs. The first digital output level, which corresponds to the synchronization pulse, may be between a supply voltage and a ground voltage, or alternatively, the first digital output level may be a ground voltage. The synchronization pulse may electrically differ from the outputs of the plurality of LEs with regard to a characteristic such as voltage, pulse-time duration, signal frequency, or signal phase. The synchronization pulse may electrically differ from the outputs of the plurality of LEs with regard to a clock burst that has a higher frequency than an LE output timeslot. The digital selector switch may include a number of switch points equal to the number of LEs in the plurality of LEs plus one (1) for the synchronization pulse. The display device may be a conventional oscilloscope. The single debug pin may be shared with one or more other functions of the FPGA when the single debug pin is not being used for debugging.

In another example, a method is provided for debugging a plurality of LEs in an FPGA, wherein each LE is associated with a particular logic state. The method may include the following steps. A synchronization pulse may be generated using a synchronization pulse generator. A connection with each LE may be established, and the particular logic state of each LE may be outputted, in turn, using a digital selector switch. The synchronization pulse and the particular logic state of each LE may be received and outputted, in turn, using an output buffer. First, second, and third digital outputs levels may be enabled using a voltage divider resistor network of first and second resistors connected to an output line of the output buffer. The digital output levels may correspond to the synchronization pulse, a low particular logic state, and a high particular logic state. The synchronization pulse and the particular logic state of each LE may be outputted, in turn, using a single debug pin connected to the output line of the output buffer after the voltage divider resistor network. The synchronization pulse and the particular logic state of each LE may be visualized, in turn, on a display device as the first, second, and third digital outputs levels.

The preceding example may further include any one or more of the following features. The FPGA may be a CLB, and the plurality of LEs may include between twenty-eight (28) and one hundred thirty-two (132) LEs. The first digital output level, which corresponds to the synchronization pulse, may be between a supply voltage and a ground voltage, or alternatively, the first digital output level be a ground voltage. The synchronization pulse may electrically differ from the outputs of the plurality of LEs with regard to a characteristic such as voltage, pulse-time duration, signal frequency, or signal phase. The synchronization pulse may electrically differ from the outputs of the plurality of LEs with regard to a clock burst that has a higher frequency than an LE output timeslot. The digital selector switch may include a number of switch points equal to the number of LEs in the plurality of LEs plus one (1) for the synchronization pulse. The display device may be a conventional oscilloscope. The method may further include sharing the single debug pin with one or more other functions of the small FPGA when the single debug pin is not being used for debugging.

In another example, a method is provided for debugging a plurality of LEs in a CLB, wherein the plurality of LEs may include between twenty-eight (28) and one hundred thirty-two (132) LEs, and wherein each LE may be associated with a particular logic state. The method may include the following steps. A synchronization pulse may be generated using a synchronization pulse generator. A connection to each LE may be established, and the particular logic state of each LE may be output, in turn, using a digital selector switch. The synchronization pulse and the particular logic state of each LE may be received and output, in turn, using an output buffer. First, second, and third digital outputs levels may be enabled using a voltage divider resistor network of first and second resistors connected to an output line of the output buffer, wherein the digital output levels correspond to the synchronization pulse, a low particular logic state, and a high particular logic state. The synchronization pulse and the particular logic state of each LE may be output, in turn, using a single debug pin connected to the output line of the output buffer after the voltage divider resistor network. The synchronization pulse and the particular logic state of each LE may be visualized, in turn, on an oscilloscope as the first, second, and third digital outputs levels. The single debug pin may be shared with one or more other functions of the CLB when the single debug pin is not being used for debugging.

The preceding example may further include any one or more of the following features. The first digital output level, which corresponds to the synchronization pulse, may be between a supply voltage and a ground voltage.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a high-level block diagram depiction of a CLB or other FPGA, including a plurality of logic elements (LEs);

FIG. 2 is an illustration of a first example system for debugging a plurality of LEs in a CLB or other FPGA, such as the CLB of FIG. 1, using only one pin;

FIG. 3 is an illustration of an example output of the first example system of FIG. 2, which might be displayed on an oscilloscope;

FIG. 4 is an illustration of a second example system for debugging a plurality of LEs in a CLB of other FPGA, such as the CLB of FIG. 1, using only one pin;

FIG. 5 is an illustration of an example output of the second example system of FIG. 3, which might be displayed on an oscilloscope; and

FIG. 6 is a flowchart of operations in an example method for debugging a plurality of LEs in a CLB or other FPGA, such as the CLB of FIG. 1, using only one pin.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

CLBs and other FPGAs include a plurality of LEs including AND, OR, NAND, and NOR gates; buffers and inverting buffers; D flip-flops; JK flip-flops; multiplexers; and four-input look-up tables (LUTs). After configuration, or programming, and prior to deployment, the logic states of at least some of the LEs commonly require debugging. For larger devices with relatively large numbers of pins, it is known to use multiple LE state outputs (e.g., FLASH FPGA), which requires multiple pins. However, for smaller devices with relatively small numbers of pins (e.g., eight pins), it is generally desirable to use as few pins as possible for debugging processes.

Examples provide a system and method for debugging a plurality of LEs in a CLB or other small FPGA using only one pin. Broadly, a synchronization pulse and a logic state of each LE are outputted, in turn, as one of three different output levels (SYNCH, low, and high) via a single debug pin connected to a display device (e.g., an oscilloscope) for visualization. In more detail, examples provide a sequential output of LE states in time multiplex with a SYNC pulse that identifies the time multiplex timeslot. The SYNC pulse is displayed followed by a time-share burst series of the particular logic state of each LE, in turn, using a single pin connected to a conventional oscilloscope or similarly suitable bench-top or hand-held tool for visualization. Examples advantageously use no LEs and so are suitable for use with extremely low LE-count CLBs. Additionally, examples advantageously allow for the visualization of LE logic states using a single debug pin while providing an easy debugging readout with a conventional oscilloscope and without reprogramming (i.e., without requiring a programming cycle). Yet further, examples are advantageously compatible with known static debugging techniques. Another advantage is that the debug pin may be shared with other functions when not being used for debugging.

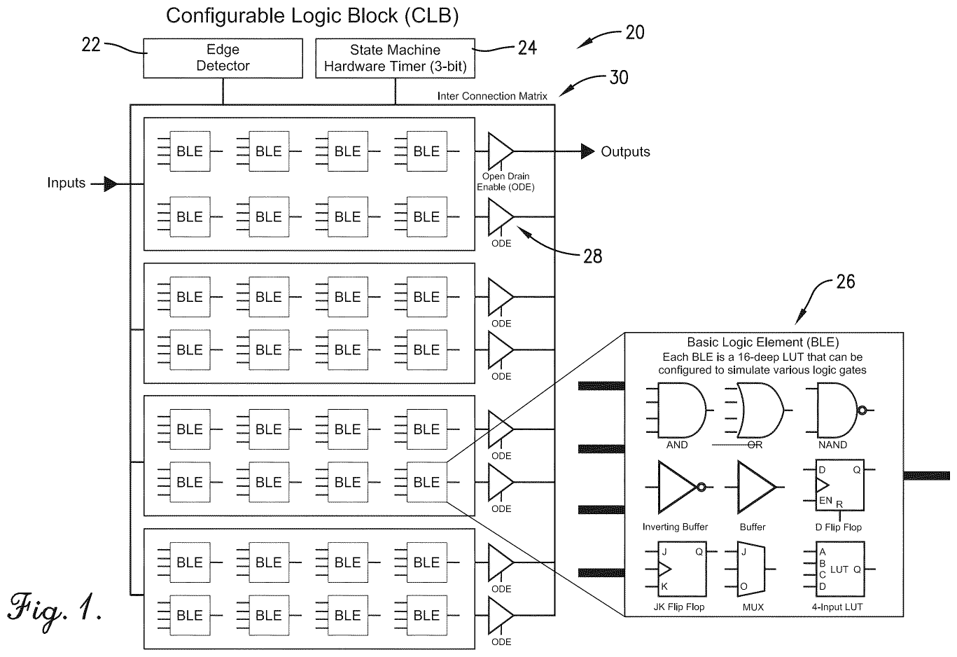

Referring to FIG. 1, a relevant portion of an example CLB or other small FPGA 20 and an example operating environment, including associated circuits, may include an edge detector 22, a state machine hardware timer 24, a plurality of basic LEs 26, a plurality of buffers 28, and an interconnection matrix 30. The edge detector 22 may be configured to detect a rising or a falling edge on an input signal. Applications for edge detection may include generating an interrupt in a microcontroller when an edge is detected, transitioning between different states when an edge is detected, and marking the timing of an event when an edge is detected. The state machine hardware timer 24 may be configured to count up or down to a set value. Applications for state machine hardware timing include triggering an event, such as an interrupt, when the set value is reached.

The plurality of basic LEs 26 may be arranged in an array and may be selectively connectable during programming of the CLB 20 to create a desired logic circuit. Typically, the plurality of LEs 26 may include approximately between twenty-eight (28) and one hundred thirty-two (132) LEs, or approximately one hundred twenty-eight (128) LEs. Typically, the plurality of LEs 26 may include some or all of AND, OR, NAND, and NOR gates; buffers and inverting buffers; D flip-flops; JK flip-flops; multiplexers; and four-input look-up tables (LUTs). The plurality of buffers 28 may be configured to store intermediate or final output signals from some or all of the LEs before the signals are sent on. In the illustrated example, there may be at least one buffer for each row of LEs in the CLB 20. The interconnection matrix 30 may be configured to carry signals between one or more input pins, the plurality of LEs 26, the plurality of buffers 28, and one or more output pins.

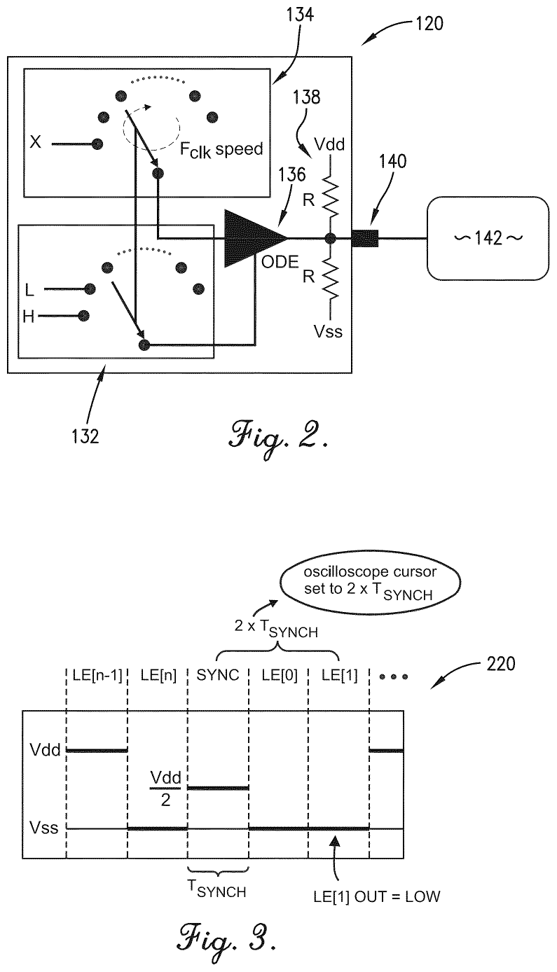

Referring to FIGS. 2 and 3, a first example system 120 for debugging a plurality of LEs in a CLB or other small FPGA (such as the plurality of LEs 26 in the CLB 20 of FIG. 1) using only one pin, and an associated operating environment may include a synchronization pulse generator 132; a digital selector switch 134; an output buffer 136; a resistor network 138; a single debug pin 140; and a display device 142. Each LE of the plurality of LEs 26 may be associated with a particular logic state, and examples of the present invention facilitate visualizing the particular logic state of some or all of the LEs to facilitate debugging to ensure that the plurality of LEs 26 have been properly selectively connected to achieve the desired circuit.

The synchronization pulse generator 132 may be configured to generate a synchronization, or SYNC, pulse prior to the system 120 outputting the particular logic state of a first LE of the plurality of LEs, thereby indicating the beginning of the series of particular logic state outputs. Thus, in time multiplex, the SYNC pulse establishes “time slot zero.” The digital selector switch 134 may be configured to connect each LE output, in turn, to the output buffer 136 for output to the debug pin 140 and visualization on the display device 142. The digital selector switch 134 may have a number of switch points equal to the number of LEs plus one (1) for the SYNC pulse. So, for example, a digital selector switch for a CLB with thirty-two (32) LEs may have thirty-three (33) switch points, while a digital selector switch for a CLB with one hundred twenty-eight (128) LEs may have one hundred twenty-nine (129) switch points. Using time multiplex to show the particular logic states of the LEs on the debug pin 140 facilitates debugging while shortening the development cycle. The SYNC pulse may differ from the LE outputs with regard to voltage, pulse-time duration, signal frequency, or signal phase, or the SYNC pulse may be distinguished by, e.g., a clock burst that has a higher frequency than the LE timeslot.

The output buffer 136 may receive and output the SYNC pulse from the synchronization pulse generator 132, and then receive and output, in turn, the output from each LE from the digital selector switch 134. The resistor network 138 may be connected to the output line from the output buffer 136 to the single debug pin 140. The resistor network 138 may be configured as a one-to-one (1:1) voltage divider with first and second resistors of the same Ohmic value. Vdd may be a positive supply voltage and Vss may be a ground voltage for the FPGA 20, and the resistor network 32 may function to convert a floating pin to an approximately middle value of the positive voltage supply, Vdd/2, which allows for first, second, and third digital output levels on the single debug pin 140. Thus, in this first example system 120, the first output level, Vdd/2, may indicate or correspond to the SYNC pulse, which marks the start of the time multiplex carousel, the second output level, Vss, may indicate a low particular logic state of an LE, and the third output level, Vdd, may indicate a high particular logic state of an LE.

The single debug pin 140 may be an existing output pin on the CLB 20 connected to the output line of the output buffer 136, wherein the resistor network 138 is interposed between the output buffer 136 and the single debug pin 140. The single debug pin 140 may be shared with one or more other functions when it is not being used for debugging. The display device 142 may be substantially any suitable bench-top or hand-held device, such as a conventional oscilloscope, for connecting to the single debug pin 140 and receiving and displaying the first, second, and third digital output levels of the output signal.

In operation, the time multiplex SYNC pulse may be output on the single debug pin 140 to the display device 142. The length of the SYNC pulse may determine the time multiplex slice duration, so setting the oscilloscope cursor to the length of the SYNC pulse facilitates identifying individual particular logic state outputs. The digital selector switch 134 cycles through the LEs and outputs, in time multiplex, each particular logic state on the single debug pin 140. As seen in FIG. 3, an example output 220 of the first example system 120 is seen on the display device 142, which, in this case, is an oscilloscope, wherein, as discussed, the system 120 is configured so that the SYNC pulse is displayed as Vdd/2, the low particular logic state is displayed as Vss, and the high particular logic state is displayed as Vdd. Once the final particular logic state is output, the process may repeat itself, beginning with the SYNC pulse which marks the start of the new time multiplex carousel.

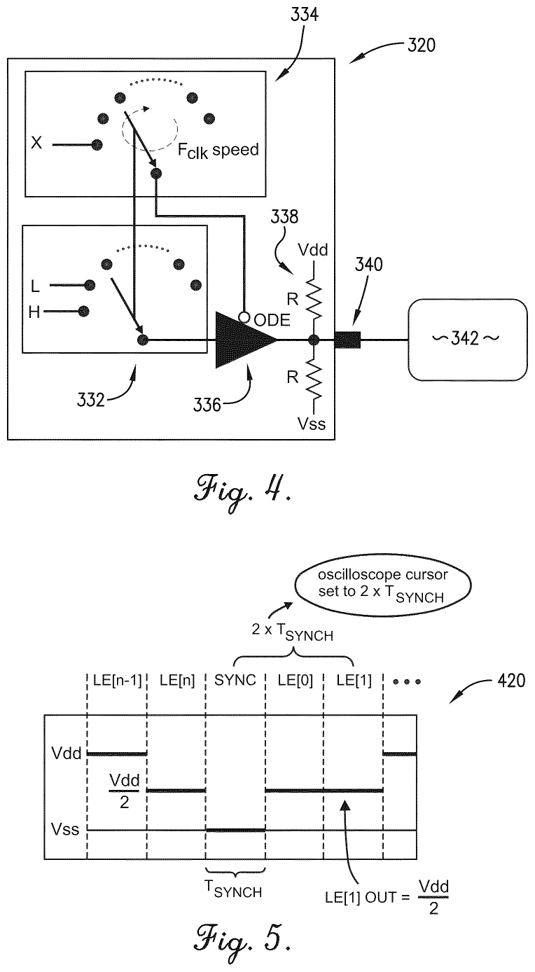

Referring to FIGS. 4 and 5, a second example system 320 for debugging a plurality of LEs in a CLB or other small FPGA (such as the plurality of LEs 26 in the CLB 20 of FIG. 1) using only one pin, and an associated operating environment may include the synchronization pulse generator 332; the digital selector switch 334; the output buffer 336; the resistor network 338; the single debug pin 340; and the display device 342. The second example system 320 may differ from the first example system 120 in that it is configured, with regard to the connections to the output buffer 336, so that the SYNC pulse is displayed as Vss and the low particular logic state is displayed as Vdd/2. The second example system 320 may be otherwise substantially similar or identical in construction and function to the first example system 120. As seen in FIG. 5, an example output of the second example system 320 is seen on the display device 342, which, in this case, is an oscilloscope, wherein, as discussed, the system 320 is configured so that the SYNC pulse is displayed as Vss, the low particular logic state is displayed as Vdd/2, and the high particular logic state is displayed as Vdd. Once the final particular logic state is output, the process may repeat itself, beginning with the SYNC pulse which marks the start of the new time multiplex carousel.

Thus, the digital output level corresponding to the SYNC pulse may be a value between the supply voltage, Vdd, and the ground voltage, Vss, such as approximately Vdd/2, as in the first example system 120, or the digital output level corresponding to the SYNC pulse may be approximately Vss, in which case the digital output level corresponding to the low particular logic state may be between Vdd and Vss (e.g., Vdd/2), as in the second example system 120.

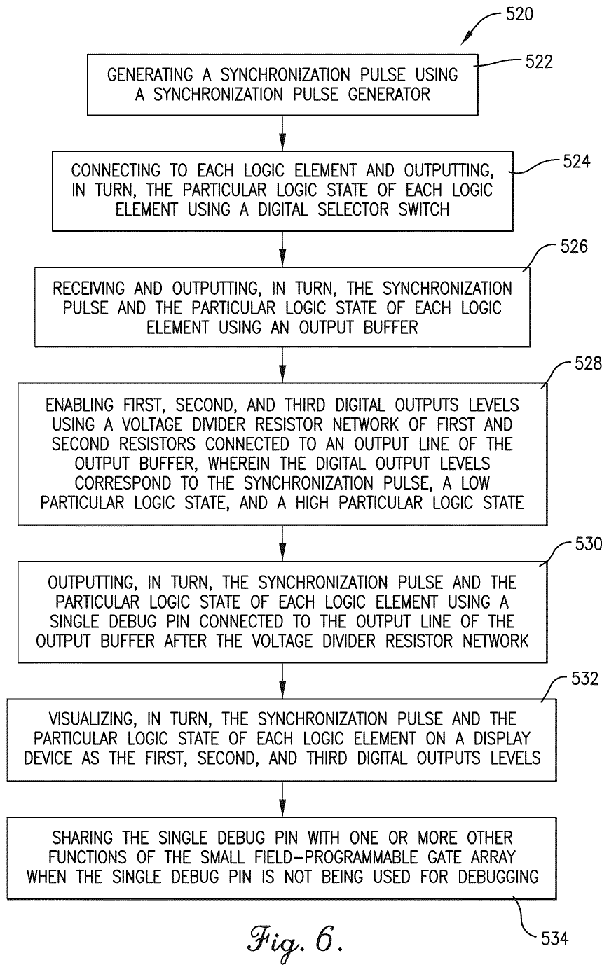

Referring to FIG. 6, a method 520 for debugging a plurality of LEs in a CLB or other small FPGA, such as the plurality of LEs 26 in the CLB 20 of FIG. 1, using only one pin may include the operations set forth below. The CLB or other FPGA may include a relatively small number of LEs (e.g., approximately between twenty-eight (28) and one hundred thirty-two (132) LEs, or approximately one hundred twenty-eight (128) LEs). Each LE of the plurality of LEs 26 may be associated with a particular logic state, and examples of the present invention facilitate visualizing the particular logic state of some or all of the LEs to facilitate debugging to ensure that the plurality of LEs 26 have been properly selectively connected to achieve the desired circuit. The method 520 may be implemented using the example systems 120, 320 described above.

A synchronization, or SYNC, pulse may be generated by the synchronization pulse generator 132, 332 prior to the outputting the particular logic state of the first LE, as shown in 522, thereby indicating the beginning of the series of particular logic state outputs. Thus, in time multiplex, the SYNC pulse establishes “time slot zero.” The synchronization pulse may differ from the LE outputs with regard to voltage, pulse-time duration, signal frequency, or signal phase, or the synchronization pulse may differ from the LE outputs with regard to a clock burst that has a higher frequency than a LE output timeslot.

The output of each LE of the plurality of LEs 26 may be connected, in turn, by the digital selector switch 134, 334, to the output buffer 136, 336, as shown in 524, for output to the debug pin 140, 340 and visualization on the display device 142, 342. The digital selector switch 134, 334 may have a number of switch points equal to the number of LEs plus one (1) for the SYNC pulse. So, for example, a digital selector switch for a CLB with thirty-two (32) LEs may have thirty-three (33) switch points, while a digital selector switch for a CLB with one hundred twenty-eight (128) LEs may have one hundred twenty-nine (129) switch points. Using time multiplex to show the logic states of the LEs states on the debug pin 140, 340 facilitates debugging while shortening the development cycle.

The SYNC pulse from the synchronization pulse generator 132, 332 may be received and then the series of outputs from each LE may be received, in turn, by the output buffer 136, 336, as shown in 526. First, second, and third digital output levels may be enabled using the resistor network 138, 338 connected to the output line from the output buffer 136, 336 to the debug pin 140, 340, as shown in 528. The resistor network 138, 338 may be configured as a one-to-one (1:1) voltage divider with first and second resistors of identical Ohmic value. The resistor network 138, 338 may convert a floating pin to an approximately middle value of the positive voltage supply (Vdd/2). Thus, the SYNC pulse may be between Vdd and Vss (e.g., Vdd/2) or it may be Vss. If the SYNC pulse is Vss, then the second digital output level corresponding to the low particular logic state may be between Vdd and Vss (e.g., Vdd/2).

The SYNC pulse may be outputted and then the series of outputs from each LE gate may be outputted, in turn, as the first, second, and third digital output levels on the single debug pin 140, 340, as shown in 530. The synchronization pulse and the particular logic state of each logic element may be visualized on the display device 142, 342 as the first, second, and third digital outputs levels, as shown in 532. The display device 142, 342 may be substantially any suitable bench-top or hand-held device, such as a conventional oscilloscope, for connecting to the debug pin 140, 340 and receiving and displaying the first, second, and third digital output levels of the output signal. The debug pin 140, 340 may be shared with one or more other functions when it is not being used for debugging, as shown in 534.

Thus, in operation, the time multiplex SYNC pulse may be output on the debug pin 140, 340 to the display device 142, 342. The length of the SYNC pulse may determine the time multiplex slice duration, so setting the oscilloscope cursor to the length of the SYNC pulse facilitates identifying individual LE state outputs. The digital selector switch 134, 334 cycles through the LEs and outputs, in time multiplex, each particular logic state on the debug pin 140, 340 to the display device 142, 342. Once the final particular logic state is output, the process may repeat itself, beginning with the SYNC pulse which marks the start of the new time multiplex carousel.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A system for debugging a plurality of logic elements in a field-programmable gate array, wherein each logic element of the plurality of logic elements is associated with a particular logic state, the system comprising:
a synchronization pulse generator configured to generate a synchronization pulse;
a digital selector switch connecting to each logic element and being configured to output, in turn, the particular logic state of each logic element;
an output buffer configured to receive and output, in turn, the synchronization pulse and the particular logic state of each logic element;
a voltage divider resistor network of first and second resistors connected to an output line of the output buffer and configured to enable first, second, and third digital outputs levels on the output line, wherein the digital output levels correspond to the synchronization pulse, a low particular logic state, and a high particular logic state; and
a single debug pin connected to the output line of the output buffer after the voltage divider resistor network and configured to be connected to a display device for visualizing, in turn, the synchronization pulse and the particular logic state of each logic element as the first, second, and third digital outputs levels.

2. The system of claim 1, wherein the field-programmable gate array is a configurable logic block, and the plurality of logic elements includes between twenty-eight (28) and one hundred thirty-two (132) logic elements.

3. The system of claim 1, wherein the first digital output level, which corresponds to the synchronization pulse, is between a supply voltage and a ground voltage.

4. The system of claim 1, wherein the first digital output level, which corresponds to the synchronization pulse, is a ground voltage.

5. The system of claim 1, wherein the synchronization pulse electrically differs from the outputs of the plurality of logic elements with regard to a characteristic selected from the group consisting of: voltage, pulse-time duration, signal frequency, and signal phase.

6. The system of claim 1, wherein the synchronization pulse electrically differs from the outputs of the plurality of logic elements with regard to a clock burst that has a higher frequency than a logic element output timeslot.

7. The system of claim 1, wherein the digital selector switch includes a number of switch points equal to the number of logic elements in the plurality of logic elements plus one (1) for the synchronization pulse.

8. The system of claim 1, wherein the display device is a conventional oscilloscope.

9. The system of claim 1, wherein the single debug pin is shared with one or more other functions of the field-programmable gate array when the single debug pin is not being used for debugging.

10. A method for debugging a plurality of logic elements in a field-programmable gate array, wherein each logic element of the plurality of logic elements is associated with a particular logic state, the method comprising:
generating a synchronization pulse using a synchronization pulse generator;
connecting to each logic element and outputting, in turn, the particular logic state of each logic element using a digital selector switch;
receiving and outputting, in turn, the synchronization pulse and the particular logic state of each logic element using an output buffer;
enabling first, second, and third digital outputs levels using a voltage divider resistor network of first and second resistors connected to an output line of the output buffer, wherein the digital output levels correspond to the synchronization pulse, a low particular logic state, and a high particular logic state;
outputting, in turn, the synchronization pulse and the particular logic state of each logic element using a single debug pin connected to the output line of the output buffer after the voltage divider resistor network; and
visualizing, in turn, the synchronization pulse and the particular logic state of each logic element on a display device as the first, second, and third digital outputs levels.

11. The method of claim 10, wherein the field-programmable gate array is a configurable logic block, and the plurality of logic elements includes between twenty-eight (28) and one hundred thirty-two (132) logic elements.

12. The method of claim 10, wherein the first digital output level, which corresponds to the synchronization pulse, is between a supply voltage and a ground voltage.

13. The method of claim 10, wherein the first digital output level, which corresponds to the synchronization pulse, is a ground voltage.

14. The method of claim 10, wherein the synchronization pulse electrically differs from the outputs of the plurality of logic elements with regard to a characteristic selected from the group consisting of: voltage, pulse-time duration, signal frequency, and signal phase.

15. The method of claim 10, wherein the synchronization pulse electrically differs from the outputs of the plurality of logic elements with regard to a clock burst that has a higher frequency than a logic element output timeslot.

16. The method of claim 10, wherein the digital selector switch includes a number of switch points equal to the number of logic elements in the plurality of logic elements plus one (1) for the synchronization pulse.

17. The method of claim 10, wherein the display device is a conventional oscilloscope.

18. The method of claim 10, further including sharing the single debug pin with one or more other functions of the small field-programmable gate array when the single debug pin is not being used for debugging.

19. A method of debugging a plurality of logic elements in a configurable logic block, wherein the plurality of logic elements includes between twenty-eight (28) and one hundred thirty-two (132) logic elements, and wherein each logic element of the plurality of logic elements is associated with a particular logic state, the method comprising:
generating a synchronization pulse using a synchronization pulse generator;
connecting to each logic element and outputting, in turn, the particular logic state of each logic element using a digital selector switch;
receiving and outputting, in turn, the synchronization pulse and the particular logic state of each logic element using an output buffer;
enabling first, second, and third digital outputs levels using a voltage divider resistor network of first and second resistors connected to an output line of the output buffer, wherein the digital output levels correspond to the synchronization pulse, a low particular logic state, and a high particular logic state;
outputting, in turn, the synchronization pulse and the particular logic state of each logic element using a single debug pin connected to the output line of the output buffer after the voltage divider resistor network;
visualizing, in turn, the synchronization pulse and the particular logic state of each logic element on an oscilloscope as the first, second, and third digital outputs levels; and
sharing the single debug pin with one or more other functions of the configurable logic block when the single debug pin is not being used for debugging.

20. The method of claim 10, wherein the first digital output level, which corresponds to the synchronization pulse, is between a supply voltage and a ground voltage.
